(19) United States
(12) Patent Application Publication
(10) Pub. No.: US 2026/0206229 A1
(43) Pub. Date: Jul. 16, 2026

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Jongyeon BAEK, Suwon-si (KR); Youngji NOH, Suwon-si (KR); Minjeong KANG, Suwon-si (KR)

(21) Appl. No.: 19/253,340

(22) Filed: Jun. 27, 2025

(30) Foreign Application Priority Data
Jan. 10, 2025 (KR) 10-2025-0004380

(51) Int. Cl. H10B 51/20; H10B 51/10; H10B 51/30; H10B 51/40

(52) U.S. Cl. CPC H10B 51/20; H10B 51/10; H10B 51/30; H10B 51/40

(57) ABSTRACT

An example semiconductor memory device includes a mold structure including a plurality of mold insulating layers and a plurality of gate electrodes, and a channel structure penetrating the mold structure in the first direction. The channel structure includes a channel layer, a ferroelectric layer and a dielectric layer sequentially arranged from the channel layer between the channel layer and the plurality of gate electrodes, and a channel pad in contact with the filling insulating layer and the channel layer. The channel pad includes a first portion in contact with an upper surface of the filling insulating layer and a second portion on the first portion and having a width larger than the width of the first portion in a second direction perpendicular to the first direction. An upper surface of the dielectric layer is positioned at a lower level than the second portion.

### CROSS-REFERENCE TO RELATED APPLICATION

This application claims priority to Korean Patent Application No. 10-2025-0004380, filed in the Korean Intellectual Property Office on Jan. 10, 2025, the entire contents of which are hereby incorporated by reference.

### BACKGROUND

A semiconductor memory device capable of storing large amounts of data may be used in electronic systems that require data storage.

Research has been conducted to increase the data storage capacity of a semiconductor device. For example, to increase the data storage capacity of a semiconductor device, a semiconductor device may include memory cells arranged three-dimensionally.

### SUMMARY

The present disclosure relates to a semiconductor memory device with improved electrical properties and a higher level of integration.

The present disclosure relates to an electronic system with improved electrical properties and a higher level of integration.

In some implementations, a semiconductor memory device includes mold structure including a plurality of mold insulating layers and a plurality of gate electrodes, the plurality of mold insulating layers and the plurality of gate electrodes are alternately stacked in a first direction, and a channel structure penetrating the mold structure in the first direction. The channel structure includes a filling insulating layer, a channel layer on a side surface of the filling insulating layer, a ferroelectric layer and a dielectric layer sequentially arranged from the channel layer between the channel layer and the plurality of gate electrodes, and a channel pad in contact with the filling insulating layer and the channel layer. In addition, the channel pad includes a first portion in contact with an upper surface of the filling insulating layer and a second portion on the first portion and having a width larger than the width of the first portion in a second direction perpendicular to the first direction. An upper surface of the dielectric layer is positioned at a lower level than the second portion.

In some implementations, a semiconductor memory device includes peripheral circuit structure and a cell structure stacked on the peripheral circuit structure. The cell structure includes a cell substrate, a mold structure including a pl urality of mold insulating layers and a plurality of gate electrodes, wherein the plurality of mold insulating layers and the plurality of gate electrodes are alternately stacked on the cell substrate in a first direction, and a channel structure in a channel hole, the channel hole penetrates the mold structure in the first direction. The channel structure includes a filling insulating layer, a channel layer on a side surface of the filling insulating layer, a ferroelectric layer including a ferroelectric material and the ferroelectric layer on a side surface of the channel layer, a dielectric layer including a high-k material and placed on a side surface of the ferroelectric layer, and a channel pad in contact with the filling insulating layer and the channel layer. The channel pad includes a first portion in contact with an upper surface of the filling insulating layer and a second portion on the first portion, the second portion having a width larger than the width of the first portion in a second direction perpendicular to the first direction, and an upper surface of the dielectric layer is positioned at a lower level than the second portion.

In some implementations, an electronic system includes a main substrate, a semiconductor memory device including a peripheral circuit structure and a cell structure stacked on the peripheral circuit structure on the main substrate, and a controller electrically connected to the semiconductor memory device on the main substrate. The cell structure includes a cell substrate, a mold structure including a pl urality of mold insulating layers and a plurality of gate electrodes, the plurality of mold insulating layers and the plurality of gate electrodes are alternately stacked on the cell substrate in a first direction, and a channel structure in a channel hole, the channel hole penetrating the mold structure in the first direction. The channel structure includes a filling insulating layer, a channel layer on a side surface of the filling insulating layer, a ferroelectric layer and a dielectric layer sequentially arranged from the channel layer between the channel layer and the plurality of gate electrodes, and a channel pad in contact with the filling insulating layer and the channel layer. The ferroelectric layer includes a ferroelectric material, and the dielectric layer includes a high-k material. The channel pad includes a first portion in contact with an upper surface of the filling insulating layer and a second portion on the first portion, the second portion having a width larger than the width of the first portion in a second direction perpendicular to the first direction, and an upper surface of the dielectric layer is positioned at a lower level than the second portion.

In some implementations, it may be possible to increase the area where a contact plug can come into contact with a channel structure without increasing the size of a channel hole.

In some implementations, it may be possible to secure a sufficient area for the contact plug to be connected to the channel structure, so the process of aligning the contact plug with the channel structure may be facilitated.

In some implementations, it may be possible to increase the width of the contact plug to be in contact with the channel structure to reduce the resistance, so that the electrical performance may be improved.

### BRIEF DESCRIPTION OF THE DRAWINGS

FIG. 1 is a plan view for illustrating an example of a semiconductor memory device.

FIG. 2 is an example cross-sectional view taken along line X-X′ in FIG. 1.

FIGS. 3, 4, 5, and 6 are partially enlarged views for illustrating an example of a semiconductor memory device.

FIGS. 7, 8, 9, 10, 11, 12, and 13 are views for illustrating an example of a method of manufacturing a semiconductor memory device.

FIG. 14 is a flowchart for illustrating an example of a method of manufacturing a semiconductor memory device.

FIGS. 15, 16, 17, 18, and 19 are views for illustrating an example of a method of manufacturing a semiconductor memory device.

FIG. 20 illustrates an example of a semiconductor memory device.

FIG. 21 is a block diagram for illustrating an example of an electronic system.

FIG. 22 is a perspective view for illustrating an example of an electronic system.

FIG. 23 is an example schematic cross-sectional view taken along line V-V in FIG. 22.

### DETAILED DESCRIPTION

With reference to the drawings below, a semiconductor memory device and an electronic system including the same will be described in detail.

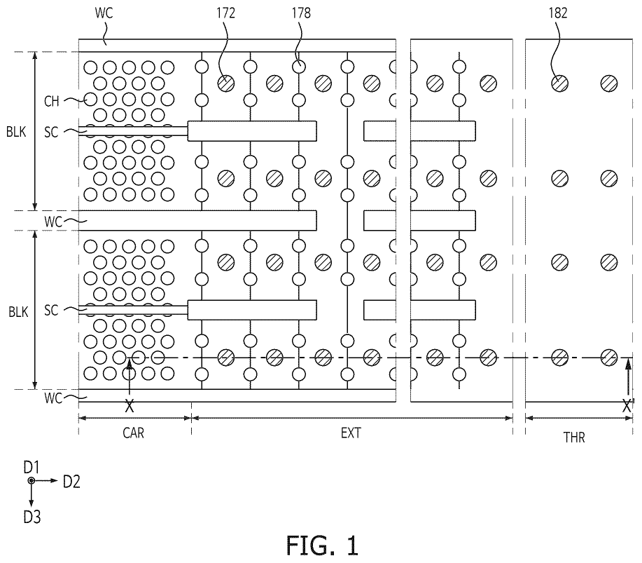

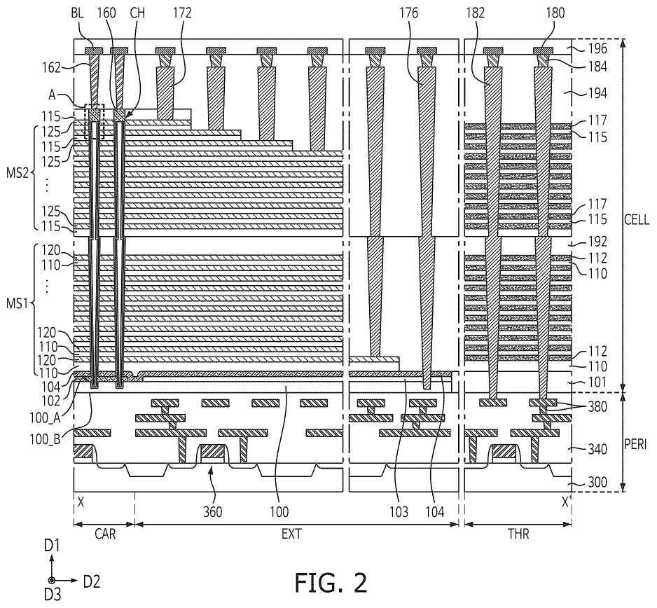

FIG. 1 is a plan view for illustrating an example of a semiconductor memory device. FIG. 2 is an example cross-sectional view taken along line X-X′ in FIG. 1.

Referring to FIGS. 1 and 2, the semiconductor memory device may include a cell structure CELL and a peripheral circuit structure PERI.

The cell structure CELL may include a cell substrate 100, a first mold structure MS1, a second mold structure MS2, a channel structure CH, a channel pad 160, a bit line BL, a word line contact 172, a source contact 176, a through via 182, a first wiring structure 180, etc.

The cell substrate 100 may include a cell array region CAR, an extension region EXT, and a through region THR.

A memory cell array including a plurality of memory cells may be formed on the cell array region CAR. The channel structure CH, the first mold structure MS1, the second mold structure MS2, the bit line BL, etc. may be arranged on the cell array region CAR.

The extension region EXT may be arranged around the cell array region CAR. For example, the extension region EXT may surround the cell array region CAR. The word line contact 172, a support structure 178, etc. may be placed on the extension region EXT.

The through region THR may be positioned outside the extension region EXT. For example, the through region THR may be arranged on one side of the extension region EXT, but the present disclosure is not limited thereto. The through via 182 may be disposed in the through region THR.

The cell substrate 100 may include a semiconductor substrate, such as a silicon substrate, a germanium substrate, and a silicon-germanium substrate. In some implementations, the cell substrate 100 may include a silicon-on-insulator (SOI) substrate, a germanium-on-insulator (GOI) substrate, etc. In some implementations, the cell substrate 100 may include polysilicon (poly Si).

The cell substrate 100 may include a first side 100_A and a second side 100_B opposing the first side 100_A. The first side 100_A of the cell substrate 100 may be a side on which the first mold structure MS1 and the channel structure CH are arranged. The first side 100_A of the cell substrate 100 may be referred to as the front side of the cell substrate 100. The second side 100_B of the cell substrate 100 may be referred to as the back side of the cell substrate 100.

The first mold structure MS1 may be formed on the first side 100_A of the cell substrate 100. The first mold structure MS1 may include a plurality of first mold insulating layers 110 and a plurality of first gate electrodes 120, which are alternately stacked in a first direction D1. Each of the first mold insulating layers 110 and each of the first gate electrodes 120 may have a layered structure in which they extend parallel to the first side 100_A of the cell substrate 100. The first gate electrodes 120 may be sequentially stacked on the cell substrate 100 while being spaced apart from each other by the first mold insulating layers 110.

The second mold structure MS2 may be formed on the first mold structure MS1. The second mold structure MS2 may include a plurality of second mold insulating layers 115 and a plurality of second gate electrodes 125, which are alternately stacked. Each of the second mold insulating layers 115 and each of the second gate electrodes 125 may have a layered structure in which they extend parallel to the first side 100_A of the cell substrate 100. The second gate electrodes 125 may be sequentially stacked on the first mold structure MS1 while being spaced apart from each other by the second mold insulating layers 115.

In some implementations, some of the plurality of first gate electrodes 120 may be used as a ground selection line GSL and an erasing control line ECL of the semiconductor memory device. For example, among the plurality of first gate electrodes 120, the first gate electrode 120 adjacent to a source structure 102 and 104 may be used as the erasing control line ECL. The erasing control line ECL may be used as a gate electrode of an erasing transistor. The erasing transistor may perform an operation of erasing a plurality of memory cell transistors by generating a gate induced drain leakage (GIDL) current. The first gate electrode 120 adjacent to the erasing control line ECL may be provided as the ground selection line GSL. However, the present disclosure is not limited thereto. The arrangement and number of the ground selection lines GSL may vary.

In some implementations, some of the plurality of second gate electrodes 125 may be provided as a string selection line SSL of the semiconductor memory device. For example, the second gate electrode 125 adjacent to the bit line BL among the plurality of second gate electrodes 125 may be provided as the string selection line SSL. However, the present disclosure is not limited thereto. The arrangement and number of the string selection lines SSL may vary.

The first mold insulating layer 110 and the second mold insulating layer 115 may respectively include an insulating material. The first mold insulating layer 110 and the second mold insulating layer 115 may each include, for example, at least one of silicon oxide, silicon nitride, and silicon oxynitride, but the present disclosure is not limited thereto.

The first gate electrode 120 and the second gate electrode 125 may respectively include a conductive material. The first gate electrode 120 and the second gate electrode 125 may respectively include, for example, a metal such as tungsten (W), cobalt (Co), and nickel (Ni) or a semiconductor material such as silicon, but the present disclosure is not limited thereto.

In FIG. 2, two mold structures MS1 and MS2 have been illustrated, but the present disclosure is not limited thereto. For example, the number of the mold structures MS1 and MS2 may be three or four or more.

The channel structure CH may penetrate each of the first mold structure MS1 and the second mold structure MS2. For example, the channel structure CH may penetrate and intersect each of the plurality of first mold insulating layers 110 and the plurality of first gate electrodes 120. The channel structure CH may penetrate and intersect each of the plurality of second mold insulating layers 115 and the plurality of second gate electrodes 125. The channel structure CH may extend in the first direction D1. The channel structure CH may have the shape of a pillar, e.g., a cylindrical shape, extending in the first direction D1.

The channel structure CH may have a bend between the first mold structure MS1 and the second mold structure MS2. In some implementations, the cross-section of the channel structure CH within the first mold structure MS1 may have an inclined side surface so that the width of the channel structure CH decreases toward the cell substrate 100. However, the present disclosure is not limited thereto.

In some implementations, the channel structures CH may be arranged in a zigzag shape. For example, as illustrated in FIG. 1, the channel structures CH may be alternately placed in a second direction D2 and a third direction D3. The level of integration of the semiconductor memory device may be improved as the channel structures CH are arranged in a zigzag shape. In some implementations, the channel structures CH may be disposed in the shape of a honeycomb.

The channel structure CH may include a channel layer, a dielectric layer, a ferroelectric layer, a channel interface layer, a filling insulating layer, and the channel pad 160.

The channel pad 160 may be disposed on the channel structure CH. The channel pad 160 may be placed on the channel structure CH and may be electrically connected to the channel layer. The channel pad 160 may include, for example, polysilicon doped with impurities, but the present disclosure is not limited thereto.

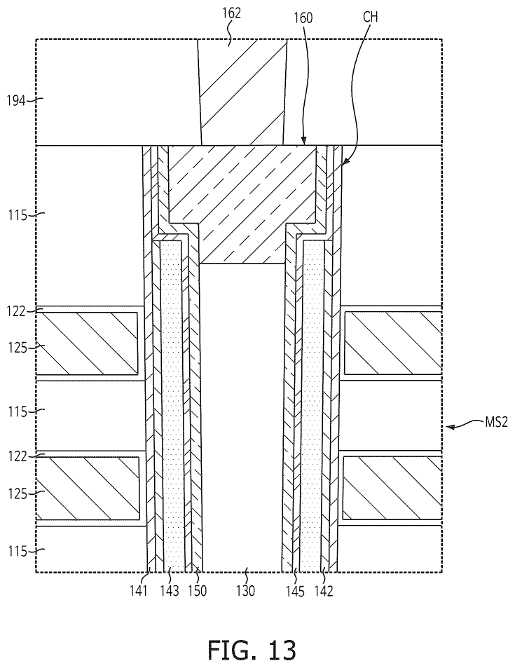

In some implementations, the source structure 102 and 104 may be formed on the cell substrate 100. The source structure 102 and 104 may be positioned between the cell substrate 100 and the first mold structure MS1. For example, the source structure 102 and 104 may extend along an upper surface of the cell substrate 100. The source structure 102 and 104 may be formed to be connected to the channel layer and/or the ferroelectric layer of the channel structure CH. Such a source structure 102 and 104 may be used as a common source line, e.g., CSL in FIG. 13, of the semiconductor memory device. The source structure 102 and 104 may include polysilicon or a metal doped with impurities, for example, but the present disclosure is not limited thereto.

In some implementations, the channel structure CH may penetrate the source structure 102 and 104. For example, a lower portion of the channel structure CH may be disposed within the cell substrate 100 through the source structure 102 and 104.

In some implementations, the source structure 102 and 104 may be multilayer. For example, the source structure 102 and 104 may include a first source layer 102 and a second source layer 104, which are sequentially stacked on the cell substrate 100. The first source layer 102 and the second source layer 104 may respectively include polysilicon doped with impurities or polysilicon not doped with impurities, but the present disclosure is not limited thereto. The first source layer 102 may be in contact with the channel layer to function as a common source line, e.g., CSL in FIG. 13, of the semiconductor memory device. The second source layer 104 may be used as a support layer to prevent the collapse of a mold stack during a replacement process for forming the first source layer 102.

Although not shown, a base insulating film may be interposed between the cell substrate 100 and the source structure 102 and 104. The base insulating film may include, for example, at least one of silicon oxide, silicon nitride, and silicon oxynitride, but the present disclosure is not limited thereto.

In some implementations, the source structure 102 and 104 may not be formed within the extension region EXT where an insulating substrate 101 is formed. In the drawing, an upper surface of the insulating substrate 101 is disposed on the same plane as an upper surface of the source structure 102 and 104, but this is only an example. In some implementations, the upper surface of the insulating substrate 101 may be positioned above the upper surface of the source structure 102 and 104.

In some implementations, a source sacrificial film 103 may be formed on a portion of the cell substrate 100. For example, the source sacrificial film 103 may be formed on a portion of the cell substrate 100 in the extension region EXT. The source sacrificial film 103 may include a material having an etching selectivity with respect to the mold insulating layers 110 and 115. For example, the mold insulating layers 110 and 115 may include silicon oxide, and the source sacrificial film 103 may include silicon nitride. The source sacrificial film 103 may be a layer remaining after a portion thereof has been replaced with the source layer 102 during the process o f manufacturing the source structure 102 and 104.

A block separation pattern WC may extend in the first direction D1 to sever the mold structure MS1 and MS2. At least a portion of the block separation pattern WC may completely cut the mold structure MS1 and MS2. At least a portion of the block separation pattern WC may partially cut the mold structure MS1 and MS2.

A string separation structure SC may extend in the second direction D2 to cut a string selection line. For example, the string separation structure SC formed within a cell block BLK may sever the string selection line. The divided string selection lines may independently control their respective regions.

The string separation structure SC may include an insulating material, i.e., at least one of silicon oxide, silicon nitride, and silicon oxynitride, but the present disclosure is not limited thereto.

The bit line BL may be formed above the mold structure MS1 and MS2. The bit line BL may extend in the third direction D3 and intersect the block separation pattern WC. In addition, the bit line BL may extend in the third direction D3 and be connected to a plurality of channel structures CH arranged in the third direction D3. For example, a bit line contact may be formed within a second interlayer insulating film 194 to be connected to the upper portion of each of the channel structures CH. The bit line BL may be electrically connected to the channel structure CH through a contact plug 162.

The contact plugs 162 may be placed on the channel structures CH. The contact plugs 162 may have a cylindrical shape, and, depending on the aspect ratio, may have an inclined side surface so that its width decreases toward the cell substrate 100. The contact plug 162 may connect the channel structure CH to the bit line BL. The bit line BL may be connected to the contact plug 162. The contact plugs 162 and the bit lines BL may be made of a conductive material, and may include, for example, at least one of tungsten (W), aluminum (Al), and copper (Cu).

The word line contact 172 may be connected to each of the gate electrodes 120 and 125. For example, the word line contact 172 may extend in the second direction D2 within the interlayer insulating film 192 and 194 and be connected to each of the gate electrodes 120 and 125. In some implementations, the word line contact 172 may have a bend between the first mold structure MS1 and the second mold structure MS2.

The source contact 176 may be connected to the source structure 102 and 104. For example, the source contact 176 may extend in the first direction D1 within the interlayer insulating film 192 and 194 and be connected to the cell substrate 100. In some implementations, the source contact 176 may have a bend between the first mold structure MS1 and the second mold structure MS2.

In some implementations, the mold structure MS1 and MS2 in the through region THR may include a plurality of mold sacrificial films 112 and 117 and a plurality of mold insulating layers 110 and 115, which are alternately stacked on the cell substrate 100 and/or the insulating substrate 101. Each of the mold sacrificial films 112 and 117 and each of the mold insulating layers 110 and 115 may have a layered structure in which they extend parallel to the upper surface of the cell substrate 100. The mold sacrificial films 112 and 117 may be sequentially stacked on the cell substrate 100 while being spaced apart from each other by the mold insulating layers 110 and 115.

In some implementations, the first mold structure MS1 in the through region THR may include the plurality of first mold sacrificial films 112 and the plurality of first mold insulating layers 110, which are alternately stacked on the cell substrate 100, and the second mold structure MS2 in the through region THR may include the plurality of second mold sacrificial films 117 and the plurality of second mold insulating layers 115, which are alternately stacked on the first mold structure MS1.

The mold sacrificial films 112 and 117 may each include an insulating material, i.e., at least one of silicon oxide, silicon nitride, and silicon oxynitride, but the present disclosure is not limited thereto. In some implementations, the mold sacrificial film 112 and 117 may include a material having an etching selectivity with respect to the mold insulating layer 110 and 115. For example, the mold insulating layers 110 and 115 may include silicon oxide, and the mold sacrificial films 112 and 117 may include silicon nitride.

The interlayer insulating film 192 and 194 may be formed on the cell substrate 100 and cover the mold structure MS1 and MS2. In some implementations, the interlayer insulating film 192 and 194 may include a first interlayer insulating film 192 and the second interlayer insulating film 194, which are sequentially stacked on the cell substrate 100. The first interlayer insulating film 192 may cover the first mold structure MS1, and the second interlayer insulating film 194 may cover the second mold structure MS2. The interlayer insulating film 192 and 194 may include, for example, at least one of silicon oxide, silicon oxynitride, and a low-k material having a lower dielectric constant than that of silicon oxide, but the present disclosure is not limited thereto.

The through via 182 may be positioned within the through region THR. For example, the through via 182 may extend in the first direction D1 within the mold structure MS1 and MS2 in the through region THR. In some implementations, the through via 182 may have a bend between the first mold structure MS1 and the second mold structure MS2. In the drawing, the through via 182 penetrates the mold structure MS1 and MS2, but this is only an example. In some implementations, the through via 182 may be positioned outside the mold structure MS1 and MS2 and may not penetrate the mold structure MS1 and MS2.

The word line contact 172, the source contact 176, and the through via 182 may be connected to the first wiring structure 180 on the interlayer insulating film 194. For example, a wiring insulating film 196 may be formed on the second interlayer insulating film 194. The first wiring structure 180 may be formed within the wiring insulating film 196. The word line contact 172, the source contact 176, and the through via 182 may each be connected to the first wiring structure 180 by a contact via 184. Although not specifically shown, the first wiring structure 180 may also be connected to the bit line BL.

In some implementations, the support structure 178 may be formed within the mold structure MS1 and MS2 in the extension region EXT. The support structure 178 may be formed in a shape similar to the channel structure CH to reduce stress applied to the mold structure MS1 and MS2 in the extension region EXT.

A peripheral circuit region PERI may include a peripheral circuit substrate 300, a peripheral circuit element 360, and a peripheral circuit wiring structure 380.

The peripheral circuit substrate 300 may be placed below the cell substrate 100. For example, an upper surface of the peripheral circuit substrate 300 may face the second side 100_B of the cell substrate 100. The peripheral circuit substrate 300 may include a semiconductor substrate, such as a silicon substrate, a germanium substrate, and a silicon-germanium substrate, for example. In some implementations, the peripheral circuit substrate 300 may include a silicon-on-insulator (SOI) substrate, a germanium-on-insulator (GOI) substrate, etc.

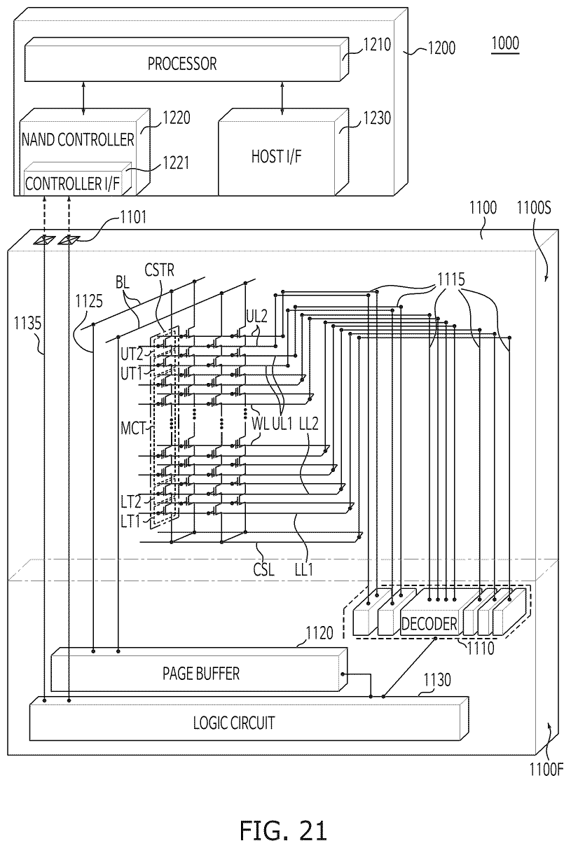

The peripheral circuit element 360 may be formed on the peripheral circuit substrate 300. The peripheral circuit element 360 may form a peripheral circuit that controls the operation of the semiconductor memory device. For example, the peripheral circuit element 360 may include a logic circuit 1130, a page buffer 1120, a decoder 1110, etc. in FIG. 21. In the following description, the surface of the peripheral circuit substrate 300 on which the peripheral circuit element 360 is arranged may be referred to as the front side of the peripheral circuit substrate 300. In contrast, the surface of the peripheral circuit substrate 300 opposite to the front side thereof may be referred to as the back side of the peripheral circuit substrate 300.

The peripheral circuit element 360 may include, for example, a transistor, but the present disclosure is not limited thereto. For example, the peripheral circuit element 360 may include various active elements such as a transistor, as well as various passive elements such as a capacitor, a resistor, and an inductor.

The peripheral circuit wiring structure 380 may be formed on the peripheral circuit element 360. For example, a peripheral wiring insulating film 340 may be formed on the front side of the peripheral circuit substrate 300, and the peripheral circuit wiring structure 380 may be formed within the peripheral wiring insulating film 340. The peripheral circuit wiring structure 380 may be electrically connected to the peripheral circuit element 360. The number of layers, the arrangement, etc. of the peripheral circuit wiring structure 380 in the drawing are merely exemplary, and the present disclosure is not limited thereto.

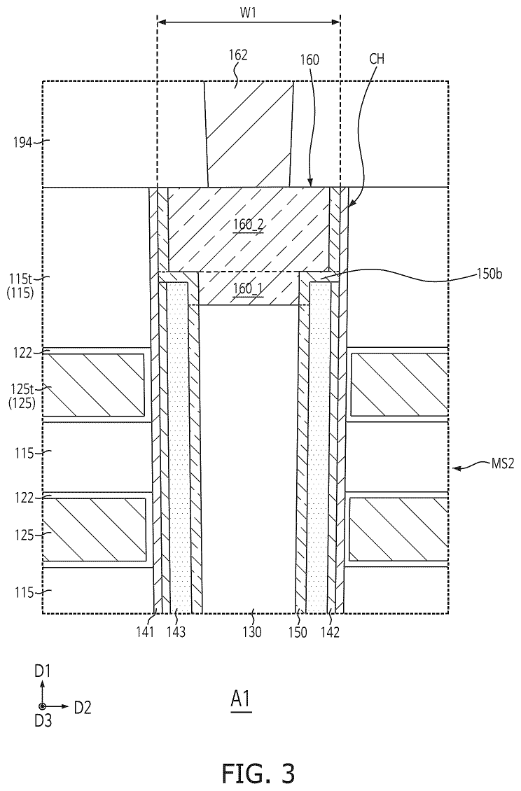

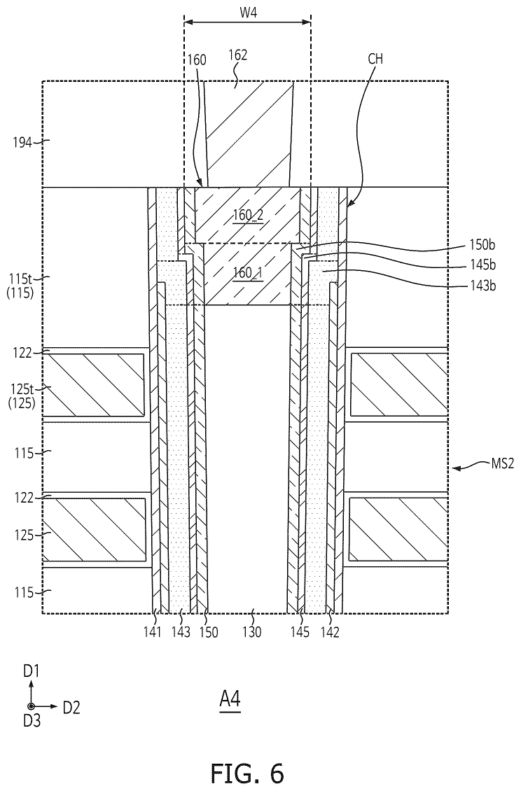

FIGS. 3, 4, 5, and 6 are partially enlarged views for illustrating an example of a semiconductor memory device. A1 in FIG. 3 to A4 in FIG. 6 may each correspond to area A in FIG. 2.

Referring to FIG. 3, the semiconductor memory device may include the mold structure and the channel structure CH.

The mold structure may correspond to the second mold structure MS2 in FIG. 2. The second mold structure MS2 may include the plurality of second mold insulating layers 115 and the plurality of second gate electrodes 125, which are alternately stacked. The plurality of second mold insulating layers 115 may include a top mold insulating layer 115t, and the plurality of second gate electrodes 125 may include a top gate electrode 125t. The top gate electrode 125t may be a gate electrode closest to the channel pad 160 among the plurality of second gate electrodes 125. The top gate electrode 125t may be a gate electrode located at the uppermost position among the plurality of second gate electrodes 125. A barrier layer 122 may be arranged on the second gate electrode 125. The barrier layer 122 may surround the second gate electrode 125. The barrier layer 122 may include a conductive material. The top mold insulating layer 115t may be a mold insulating layer located at the uppermost position among the plurality of mold insulating layers 115. In some implementations, the top mold insulating layer 115t may be formed separately from the rest of the mold insulating layers 115.

The channel structure CH may penetrate the second mold structure MS2 in the first direction D1. The channel structure CH may be placed in a channel hole penetrating the second mold structure MS2 in the first direction. The channel structure CH may include a filling insulating layer 130, a ferroelectric layer 143, a dielectric layer 142, a gate interface layer 141, a channel layer 150, and the channel pad 160.

The filling insulating layer 130 may be arranged to fill the inside of the channel layer 150. The filling insulating layer 130 may be in contact with a lower surface of the channel pad 160. An upper surface of the filling insulating layer 130 may be located at a higher level than the top gate electrode 125t. The filling insulating layer 130 may include an insulating material. For example, the filling insulating layer 130 may include at least one of silicon oxide (SiO), silicon nitride (SiN), and silicon oxynitride (SiON).

The channel layer 150 may extend in the first direction D1 and penetrate the first mold structure MS1 and the second mold structure MS2. The channel layer 150 may be arranged on a side surface of the filling insulating layer 130. The channel layer 150 may fully cover an inner wall of the ferroelectric layer 143. Although the channel layer 150 in the shape of a cup has been illustrated, the present disclosure is not limited thereto. The channel layer 150 may have various shapes, such as a cylindrical shape, the shape of a square cylinder shape, and the shape of a solid filler. The channel layer 150 may include a semiconductor material such as single crystal silicon, polycrystalline silicon, organic semiconductor material, and carbon nanostructure, but the present disclosure is not limited thereto.

The channel pad 160 may be in contact with the filling insulating layer 130 and the channel layer 150. The channel pad 160 may be placed on the upper surface of the filling insulating layer 130. The channel pad 160 may be positioned at an upper portion of the channel hole. The channel pad 160 may form an upper surface of the channel structure CH. The channel pad 160 may fill the inner space of the channel layer 150. The lower surface of the channel pad 160 may be in contact with the upper surface of the filling insulating layer 130.

The channel pad 160 may include the same material as that of the channel layer 150, but the present disclosure is not limited thereto. The channel pad 160 may include, for example, an n-type semiconductor layer. For example, the channel pad 160 may include silicon (Si), and may be formed of a polycrystalline silicon layer. When the channel pad 160 and the channel layer 150 are made of the same material, the boundary between the channel pad 160 and the channel layer 150 may not be identified.

The channel pad 160 may include a first portion 160_1 and a second portion 160_2. The first portion 160_1 may be in contact with the upper surface of the filling insulating layer 130. The second portion 160_2 may be disposed on the first portion 160_1. The second portion 160_2 may have a width larger than that of the first portion 160_1 in a second direction D2. For example, the first portion 160_1 and the second portion 160_2 may have a cylinder-like shape, and the diameter of the second portion 160_2 may be greater than that of the first portion 160_1. That is, in the second direction D2, the width of the second portion 160_2 may be larger than the width of the first portion 160_1. In addition, in a third direction D3, the width of the second portion 160_2 may be larger than the width of the first portion 160_1.

An upper surface of the channel layer 150 may be coplanar with an upper surface of the channel pad 160. That is, the upper surface of the channel layer 150 may be coplanar with an upper surface of the second portion 160_2 of the channel pad 160. The upper surface of the channel layer 150 and the upper surface of the channel pad 160 may substantially form a single plane. The upper surface of the channel layer 150 and the upper surface of the channel pad 160 may each be coplanar with an upper surface of the top mold insulating layer 115t.

The contact plug 162 may be placed on the upper surface of the channel structure CH. The contact plug 162 may electrically connect the channel structure CH and the bit line. A lower surface of the contact plug 162 may be in contact with the upper surface of the channel structure CH. The area where the contact plug 162 can come into contact with the upper surface of the channel structure CH may correspond to the upper surface of the channel pad 160 and the upper surface of the channel layer 150. The area where the contact plug 162 can come into contact with the upper surface of the channel structure CH may have a first width W1. The first width W1 may correspond to the width of an upper side of the channel hole in the second direction minus the width of the gate interface layer 141. That is, in the second direction D2, the first width W1 may correspond to the width of the upper surface of the second portion 160_2 and the upper surface of the channel layer 150.

In the case of the semiconductor memory device, it may be possible to increase the area where the contact plug 162 can come into contact with the channel structure CH without increasing the size of the channel hole. That is, because it may be possible to secure a sufficient area for the contact plug 162 to be connected to the channel structure CH, the process of aligning the contact plug 162 with the channel structure CH may be facilitated. In addition, it may be possible to increase the width of the contact plug 162 to be in contact with the channel structure CH to reduce the resistance, so that the electrical performance may be improved.

The channel layer 150 may include a channel bend 150b bent along the first portion 160_1 and the second portion 160_2 of the channel pad 160. The channel bend 150b may correspond to each of a side surface of the first portion 160_1 and a lower surface of the second portion 160_2. The channel bend 150b may include a section extending along the side surface of the first portion 160_1, i.e., a first section, and a section extending along the lower surface of the second portion 160_2, i.e., a second section. The channel bend 150b may be formed along the side surface of the first portion 160_1 and the lower surface of the second portion 160_2. The channel bend 150b may be formed along an inner surface and an upper surface of the ferroelectric layer 143. The channel bend 150b may be in contact with each of the first portion 160_1 of the channel pad 160 and the lower surface of the second portion 160_2 thereof. The channel bend 150b may overlap the first portion 160_1 of the channel pad 160 in the second direction D2. The channel bend 150b may be located at a lower level than the second portion 160_2 of the channel pad 160.

The dielectric layer 142 and the ferroelectric layer 143 may be placed within the channel hole. The dielectric layer 142 and the ferroelectric layer 143 may extend to a lower surface of the channel structure CH within the channel hole. The dielectric layer 142 and the ferroelectric layer 143 may be arranged between the plurality of second gate electrodes 125 and the channel layer 150. The dielectric layer 142 and the ferroelectric layer 143 may be placed sequentially from the channel layer 150.

The ferroelectric layer 143 may be disposed on the channel layer 150. The ferroelectric layer 143 may extend in the first direction D1. The dielectric layer 142 may be placed on the ferroelectric layer 143. The dielectric layer 142 may extend in the first direction D1 along the ferroelectric layer 143. The dielectric layer 142 may be arranged between the plurality of second gate electrodes 125 and the channel layer 150.

An upper surface of the dielectric layer 142 may be located at a level lower than the second portion 160_2 of the channel pad 160. The upper surface of the dielectric layer 142 may be positioned at a level higher than a lower surface of the first portion 160_1 of the channel pad 160. In addition, the upper surface of the dielectric layer 142 may be located at a level higher than an upper surface of the top gate electrode 125t. The lower surface of the first portion 160_1 of the channel pad 160 may be positioned at a level lower than the upper surface of the dielectric layer 142. The upper surface of the dielectric layer 142 may overlap the first portion 160_1 of the channel pad 160 in the second direction D2. In some implementations, the upper surface of the dielectric layer 142 may be in contact with the channel bend 150b. For example, when the ferroelectric layer 143 is thin, the upper surface of the dielectric layer 142 may overlap the first portion 160_1 of the channel pad 160 in the first direction D1 or may be in contact with the channel bend 150b.

At least a portion of the dielectric layer 142 may be in contact with the channel bend 150b. The upper surface of the dielectric layer 142 may be in contact with the channel bend 150b. The upper surface of the dielectric layer 142 may overlap the first portion 160_1 of the channel pad 160 and the channel bend 150b in the second direction D2.

The thickness of the dielectric layer 142 may be smaller than the thickness of the ferroelectric layer 143. Here, the thickness may be a thickness in a direction perpendicular to the direction in which the dielectric layer 142 and the ferroelectric layer 143 extend. For example, when the dielectric layer 142 extends in the first direction D1, the thickness of the dielectric layer 142 may be a thickness in the second direction D2 or the third direction D3. For another example, when the dielectric layer 142 has a tapered shape in which the width becomes narrower toward the bottom, the thickness of the dielectric layer 142 may be a thickness in the direction perpendicular to the longitudinal direction in which the dielectric layer 142 extends.

The dielectric layer 142 may include a high-k material. For example, the high-k material may mean a dielectric material having a dielectric constant higher than that of silicon dioxide (SiO₂). The dielectric layer 142 may not include a ferroelectric material. By the dielectric layer 142, the ferroelectric properties, e.g., the polarization state of the ferroelectric layer, of the ferroelectric layer 143 may be stably maintained. In some implementations, the dielectric layer 142 may include HfO₂, ZrO₂, SiO₂, SiN, TiO₂, Al₂O₃, VO₂, or a combination thereof.

The upper surface of the ferroelectric layer 143 may be located at a level lower than the second portion 160_2 of the channel pad 160. The upper surface of the ferroelectric layer 143 may be positioned at a level higher than the upper surface of the top gate electrode 125t. The upper surface of the ferroelectric layer 143 may be coplanar with the upper surface of the dielectric layer 142. The upper surface of the ferroelectric layer 143 and the upper surface of the dielectric layer 142 may form a surface parallel to the upper surface of the channel pad 160. The upper surface of the ferroelectric layer 143 and the upper surface of the dielectric layer 142 may substantially form a single surface. In some implementations, the upper surface of the ferroelectric layer 143 and the upper surface of the dielectric layer 142 may form a rounded surface.

At least a portion of the ferroelectric layer 143 may be in contact with the channel bend 150b. The upper surface of the ferroelectric layer 143 may be in contact with the channel bend 150b. The upper surface of the ferroelectric layer 143 may overlap the first portion 160_1 of the channel pad 160 and the channel bend 150b in the second direction D2.

The ferroelectric layer 143 may include a ferroelectric material. For example, the ferroelectric layer 143 may include a hafnium-based compound having ferroelectric properties. For example, the ferroelectric layer 143 may include HfO₂, HfZnO, HfSiO, HfSiON, HfTaO, HfTiO, HfZrO, or a combination thereof. In addition, the ferroelectric layer 143 may include a ferroelectric material having a perovskite structure, such as PbZrxTi1−xO₃ (PZT), BaTiO₃, and PbTiO₃. The ferroelectric layer 143 may include at least one dopant selected from carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La). The ferroelectric layer 143 may be formed of a crystal. For example, the ferroelectric layer 143 may have an orthorhombic system crystal structure.

The gate interface layer 141 may be arranged on a sidewall of the channel hole. The gate interface layer 141 may be adjacent to the plurality of second gate electrodes 125. The gate interface layer 141 may be in contact with the barrier layer 122 and the second mold insulating layer 115. The gate interface layer 141 may be disposed on a side surface of the dielectric layer 142. The gate interface layer 141 may be placed between the dielectric layer 142 and the plurality of second gate electrodes 125. The gate interface layer 141 may facilitate the inflow of charge through the gate electrode 120 and 125 but prevent the outflow of charge. In some implementations, the gate interface layer 141 may include silicon oxide (SiO).

An upper surface of the gate interface layer 141 may be coplanar with each of the upper surface of the channel layer 150 and the upper surface of the channel pad 160. The upper surface of the gate interface layer 141 may substantially form one single plane with the upper surfaces of the channel layer 150 and the channel pad 160. The upper surface of the gate interface layer 141 may be coplanar with each of the upper surface of the channel layer 150, the upper surface of the channel pad 160, and the upper surface of the top mold insulating layer 115t.

Hereinafter, a semiconductor memory device other than the semiconductor memory device in FIG. 3 will be described. The same reference numerals will be given to the same components as those illustrated in FIG. 3, and detailed descriptions thereof may be skipped.

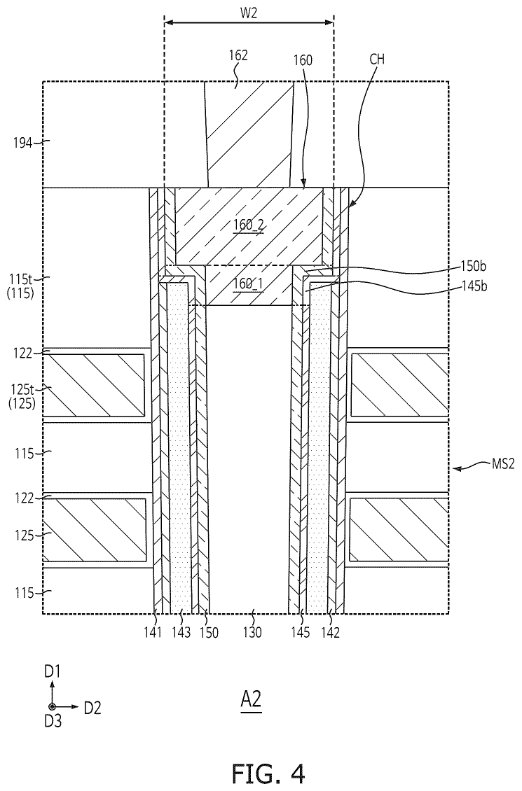

Referring to FIG. 4, a channel structure CH may further include a channel interface layer 145.

The channel interface layer 145 may be disposed on a side surface of the channel layer 150. The channel interface layer 145 may be placed between the channel layer 150 and the gate interface layer 141. An upper surface of the channel interface layer 145 may be coplanar with the upper surface of the channel pad 160. The upper surface of the channel interface layer 145 and the upper surface of the second portion 160_2 of the channel pad 160 may substantially form one single plane. For example, the channel interface layer 145 may include silicon oxynitride (SiON), silicon oxide (SiO), aluminum oxide (AlO), etc.

The channel interface layer 145 may include an interface bend 145b corresponding to the channel bend 150b. The interface bend 145b may include a portion extending along the first section of the channel bend 150b and a portion extending along the second section of the channel bend 150b. The portion extending along the second section of the channel bend 150b may be in contact with the gate interface layer 141. The portion of the interface bend 145b extending along the first section of the channel bend 150b may be in contact with a side surface of the ferroelectric layer 143, and the portion of the interface bend 145b extending along the second section of the channel bend 150b may be in contact with the upper surface of the ferroelectric layer 143 and the upper surface of the dielectric layer 142.

The interface bend 145b may overlap the first portion 160_1 of the channel pad 160 and the channel bend 150b in a second direction D2. The interface bend 145b may be in contact with the dielectric layer 142 and the ferroelectric layer 143. For example, the interface bend 145b may be in contact with the upper surface of the dielectric layer 142 and the upper and side surfaces of the ferroelectric layer 143.

A portion of the channel interface layer 145 may be positioned between the channel layer 150 and the gate interface layer 141. For example, a portion of the channel interface layer 145 at a higher level than the interface bend 145b may be located between the channel layer 150 and the gate interface layer 141.

The area where the contact plug 162 can come into contact with the upper surface of the channel structure CH may have a second width W2. That is, in the second direction D2, the second width W2 may correspond to the width of the upper surface of the second portion 160_2 and the upper surface of the channel layer 150. The s econd width W2 may correspond to the width of an upper end of a channel hole in the second direction minus the width of the upper surface of the channel interface layer 145 and the width of the upper surface of the gate interface layer 141.

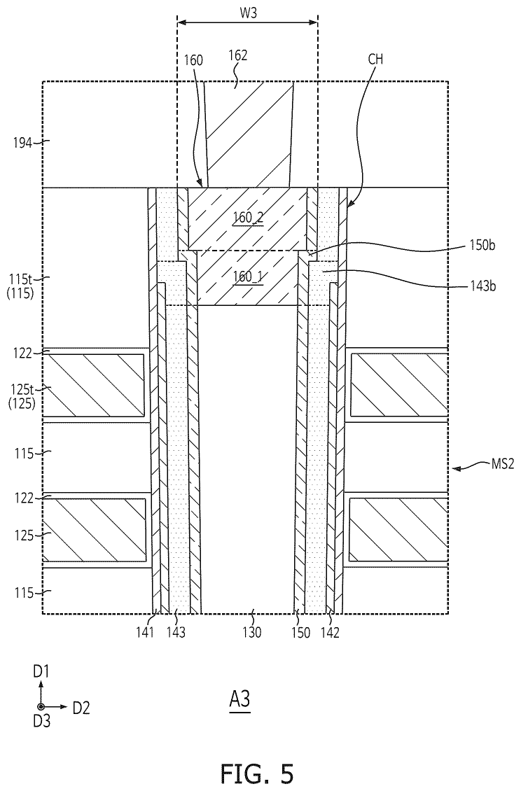

The channel structure CH in FIG. 5 may be different from the channel structure in FIG. 3 in the structure of the ferroelectric layer 143.

The ferroelectric layer 143 may extend from the top to the bottom of the channel structure CH. The upper surface of the ferroelectric layer 143 may be coplanar with the upper surface of the channel pad 160. The upper surface of the ferroelectric layer 143 may be coplanar with each of the upper surface of the channel layer 150 and the upper surface of the channel pad 160. The upper surface of the ferroelectric layer 143 may substantially form one single plane with the upper surfaces of the channel layer 150 and the channel pad 160. The upper surface of the ferroelectric layer 143 may be coplanar with each of the upper surface of the channel layer 150, the upper surface of the channel pad 160, and the upper surface of the top mold insulating layer 115t.

The ferroelectric layer 143 may include a ferroelectric bend 143b corresponding to the channel bend 150b. The ferroelectric bend 143b may include a portion extending along the first section of the channel bend 150b and a portion extending along the second section of the channel bend 150b. The portion extending along the second section of the channel bend 150b may be in contact with the gate interface layer 141. The portion of the ferroelectric bend 143b extending along the first section of the channel bend 150b may be in contact with the side surface of the dielectric layer 142, and the portion corresponding to the second section of the channel bend 150b may be in contact with the upper surface of the ferroelectric layer 143 and the upper surface of the dielectric layer 142.

The ferroelectric bend 143b may be in contact with the channel bend 150b. The ferroelectric bend 143b may overlap the first portion 160_1 of the channel pad 160 in a second direction D2. The ferroelectric bend 143b may be in contact with the dielectric layer 142. For example, the ferroelectric bend 143b may be in contact with the upper surface of the dielectric layer 142.

The ferroelectric bend 143b may be positioned at a lower level than the second portion 160_2 of the channel pad 160. The ferroelectric bend 143b may be spaced apart from the second portion 160_2 of the channel pad 160 in a first direction D1.

The area where the contact plug 162 can come into contact with the upper surface of the channel structure CH may have a third width W3. That is, in the second direction D2, the third width W3 may correspond to the width of the upper surface of the second portion 160_2 and the upper surface of the channel layer 150. The t hird width W3 may correspond to the width of an upper end of a channel hole in the second direction minus the width of the upper surface of the ferroelectric layer 143 and the width of the upper surface of the gate interface layer 141.

The channel structure CH in FIG. 6 may further include the channel interface layer 145 compared to the channel structure in FIG. 5.

The channel interface layer 145 may be disposed on the side surface of the channel layer 150. The channel interface layer 145 may be placed between the channel layer 150 and the ferroelectric layer 143. The upper surface of the channel interface layer 145 may be coplanar with the upper surface of the channel pad 160. The upper surface of the channel interface layer 145 and the upper surface of the second portion 160_2 of the channel pad 160 may substantially form one single plane. For example, the channel interface layer 145 may include silicon oxynitride (SiON), silicon oxide (SiO), aluminum oxide (AlO), etc.

The channel interface layer 145 may include an interface bend 145b corresponding to the channel bend 150b. The interface bend 145b may include a portion extending along the first section of the channel bend 150b and a portion extending along the second section of the channel bend 150b. The portion extending along the second section of the channel bend 150b may be in contact with the gate interface layer 141. The interface bend 145b may be in contact with each of the channel bend 150b and the ferroelectric bend 143b.

A portion of the channel interface layer 145 may be located between the channel layer 150 and the gate interface layer 141. For example, a portion of the channel interface layer 145 at a higher level than the interface bend 145b may be positioned between the channel layer 150 and the gate interface layer 141.

The area where the contact plug 162 can come into contact with the upper surface of the channel structure CH may have a fourth width W4. That is, in a second direction D2, the fourth width W4 may correspond to the width of the upper surface of the second portion 160_2 and the upper surface of the channel layer 150. The f ourth width W4 may correspond to the width of an upper end of a channel hole in the second direction minus the widths of the upper surfaces of the channel interface layer 145, the upper surface of the ferroelectric layer 143, and the upper surface of the gate interface layer 141.

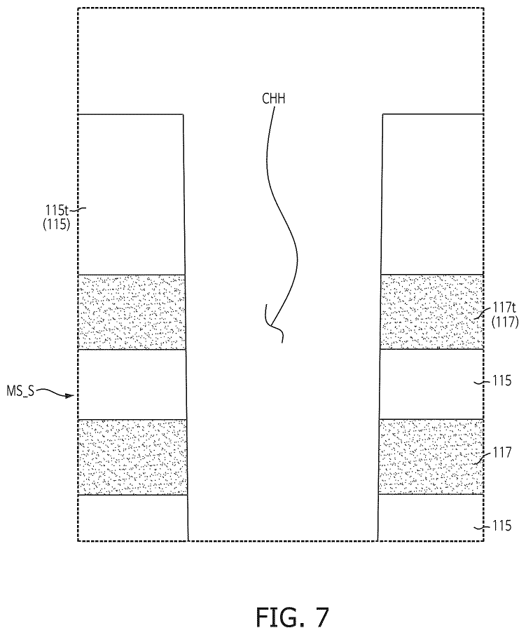

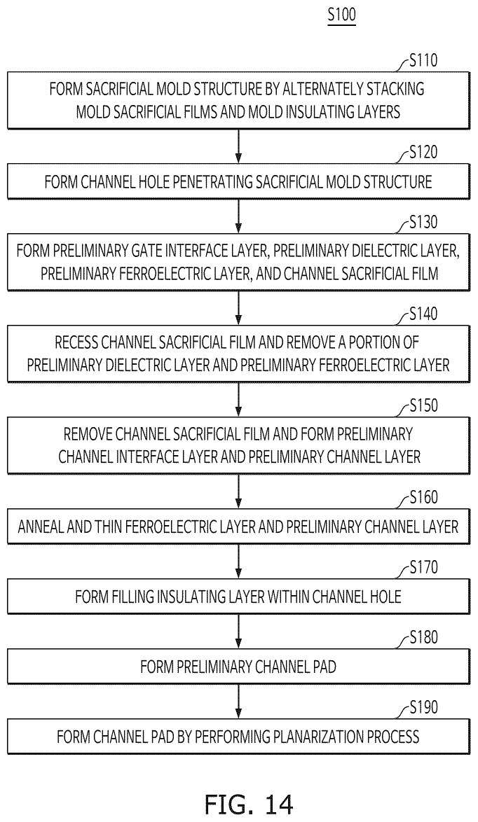

FIGS. 7, 8, 9, 10, 11, 12, and 13 are views for illustrating an example of a method of manufacturing a semiconductor memory device. FIG. 14 is a flowchart for illustrating an example of method of manufacturing a semiconductor memory device. FIGS. 7 to 13 may correspond to FIGS. 3 and 4.

Referring to FIGS. 7 and 14, a sacrificial mold structure MS_S may be formed by alternately stacking the plurality of mold sacrificial films 117 and the plurality of mold insulating layers 115 on a substrate S110.

The sacrificial mold structure MS_S may be formed by stacking the plurality of mold sacrificial films 117 and the plurality of mold insulating layers 115 in a first direction D1. Some of the mold sacrificial films 117 may be replaced with gate electrodes e.g., 125 in FIG. 2, through a subsequent process.

The mold sacrificial film 117 may be made of a material different from that of the mold insulating layer 115, and may include a material having an etching selectivity with respect to the mold insulating layer 115. For example, the mold insulating layer 115 may include at least one of silicon oxide and silicon nitride. The mold sacrificial film 117 may be made of one of silicon, silicon oxide, silicon carbide, and silicon nitride, which is a material different from that of the mold insulating layer 115.

The top mold insulating layer 115t may be formed on the top layer of the sacrificial mold structure MS_S. The top mold insulating layer 115t may be formed on a top mold sacrificial film 117t.

A channel hole CHH penetrating the sacrificial mold structure MS_S may be formed S120.

A mask pattern may be placed on an upper surface of the sacrificial mold structure MS_S, and an etching process may be performed. For example, dry etching or anisotropic etching may be carried out. By the etching, the channel hole CHH penetrating the sacrificial mold structure MS_S in the first direction D1 may be formed in the sacrificial mold structure MS_S. The channel hole CHH may have a tapered shape in which the width gradually decreases in the depth direction.

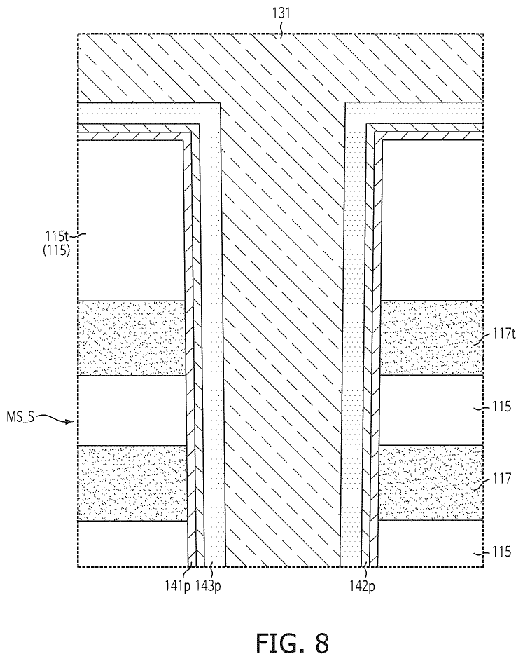

Referring to FIGS. 8 and 14, a preliminary gate interface layer 141p, a preliminary dielectric layer 142p, a preliminary ferroelectric layer 143p, and a channel sacrificial film 131 may be formed in the sacrificial mold structure MS_S in which the channel hole CHH has been formed S130.

The preliminary gate interface layer 141p, the preliminary dielectric layer 142p, the preliminary ferroelectric layer 143p, and the channel sacrificial film 131 may be sequentially formed within the channel hole CHH. The preliminary gate interface layer 141p, the preliminary dielectric layer 142p, and the preliminary ferroelectric layer 143p may be conformally formed within the channel hole CHH and on the upper surface of the sacrificial mold structure MS_S. For example, each of the preliminary gate interface layer 141p, the preliminary dielectric layer 142p, and the preliminary ferroelectric layer 143p may be formed to have a uniform thickness through the atomic layer deposition (ALD) process or the chemical vapor deposition (CVD) process.

The channel sacrificial film 131 may be placed within the channel hole CHH and on an upper surface of the preliminary ferroelectric layer 143p. The channel sacrificial film 131 may cover the upper surface of the preliminary ferroelectric layer 143p. The channel sacrificial film 131 may include a material that is easy to fill the channel hole CHH. The channel sacrificial film 131 may include a material having an etching selectivity with respect to the preliminary dielectric layer 142p and the preliminary ferroelectric layer 143p. For example, the channel sacrificial film 131 may include polysilicon (Poly Si), amorphous carbon, silicon oxide, silicon nitride, etc., but the present disclosure is not limited thereto.

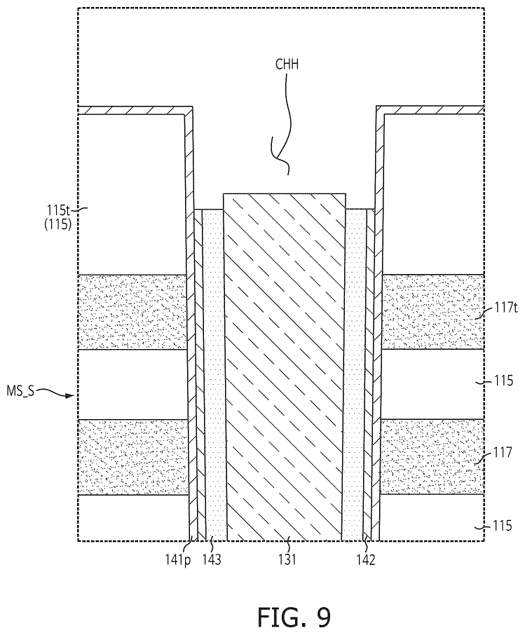

Referring to FIGS. 9 and 14, the channel sacrificial film may be recessed, and a portion of the preliminary dielectric layer and the preliminary ferroelectric layer may be removed S140.

A recessing process may be performed on the channel sacrificial film 131. For example, the channel sacrificial film 131 may be recessed by a cleaning or a wet etching, but the present disclosure is not limited thereto. While the channel sacrificial film 131 is recessed, the preliminary gate interface layer 141p, the preliminary dielectric layer 142p, and the preliminary ferroelectric layer 143p may not be etched.

The channel sacrificial film 131 may be recessed to a predetermined depth. For example, the channel sacrificial film 131 may be positioned at a higher level than the top mold sacrificial film 117t.

An etching process may be performed on the preliminary dielectric layer 142p and the preliminary ferroelectric layer 143p. By the etching process, a portion of each of the preliminary dielectric layer 142p and the preliminary ferroelectric layer 143p may be removed. Each of the preliminary dielectric layer 142p and the preliminary ferroelectric layer 143p may be removed to a level lower than an upper surface of the channel sacrificial film 131. For example, a portion of each of the preliminary dielectric layer 142p and the preliminary ferroelectric layer 143p may be removed by a wet etching. However, the present disclosure is not limited thereto, and, when the preliminary dielectric layer 142p and the preliminary ferroelectric layer 143p have an etching selectivity with respect to the channel sacrificial film 131 and the preliminary gate interface layer 141p, they may be removed by other etching methods.

As such, a portion of each of the preliminary dielectric layer 142p and the preliminary ferroelectric layer 143p may be removed to form the dielectric layer 142 and the ferroelectric layer 143. The upper surface of each of the dielectric layer 142 and the ferroelectric layer 143 may be positioned at a lower level than the upper surface of the channel sacrificial film 131.

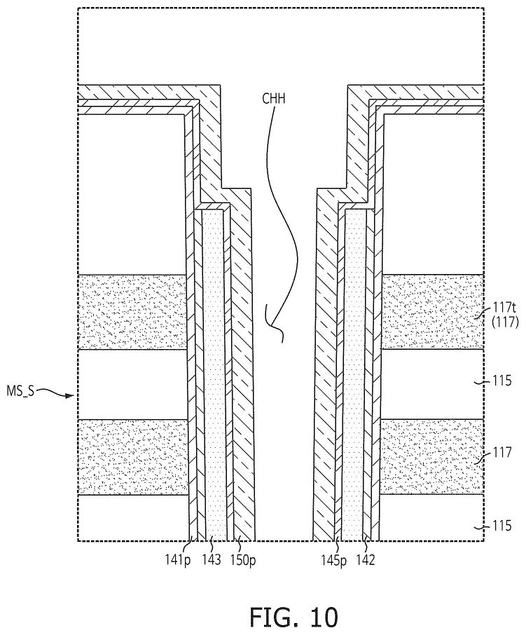

Referring to FIGS. 10 and 14, the channel sacrificial film may be removed, and a preliminary channel interface layer and a preliminary channel layer may be formed S150.

The channel sacrificial film, e.g., 131 in FIG. 9, may be removed by a cleaning or a wet etching process. The channel sacrificial film 131 may have an etching selectivity with respect to the preliminary gate interface layer 141p, the dielectric layer 142, and the ferroelectric layer 143. Therefore, while the channel sacrificial film 131 is removed, the preliminary gate interface layer 141p, the dielectric layer 142, and the ferroelectric layer 143 may not be removed.

A preliminary channel interface layer 145p and a preliminary channel layer 150p may be formed inside the channel hole CHH and on the upper surfaces of the preliminary gate interface layer 141p, the dielectric layer 142, and the ferroelectric layer 143. When the channel structure CH in FIG. 3 is manufactured, the step of forming the preliminary channel interface layer 145p may be skipped. The preliminary channel interface layer 145p and the preliminary channel layer 150p may be formed after the dielectric layer 142 and the ferroelectric layer 143 are formed, thereby forming an interface bend, e.g., 145b in FIG. 4, and a channel bend, e.g., 150b in FIG. 4. The preliminary channel layer 150p may be formed to have a uniform thickness, for example, by the chemical vapor deposition (CVD) process. The preliminary channel layer 150p may be formed to be thicker than a channel layer, e.g., 150 in FIG. 3.

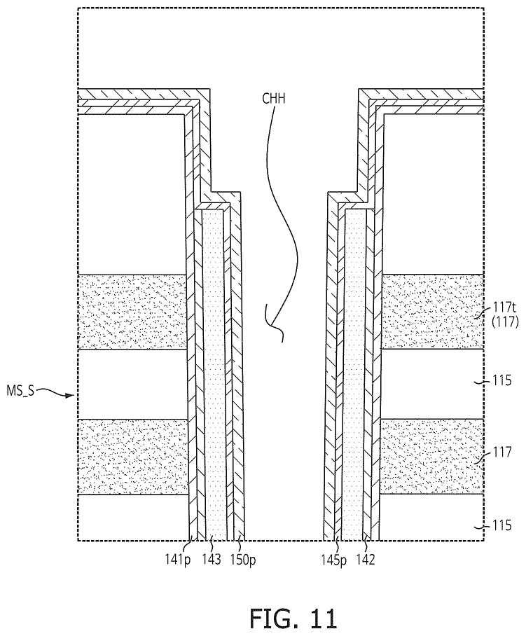

Referring to FIGS. 11 and 14, the ferroelectric layer and the preliminary channel layer may be annealed and thinned S160.

An annealing process may be performed on the dielectric layer 142, the ferroelectric layer 143, and the preliminary channel layer 150p, and a thinning process may be carried out on the preliminary channel layer 150p. The annealing process may include a step of heat treatment at a high temperature. For example, the annealing process may heat treat the ferroelectric layer 143 and the preliminary channel layer 150p at a temperature of around 300° C. to 1,200° C., but the present disclosure is not limited thereto. The thinning process may be performed by a cleaning or a wet etching.

Through the annealing process, the dielectric layer 142 and the ferroelectric layer 143 may be crystallized to become crystalline. In addition, through the annealing process and the thinning process, the thickness of the preliminary channel layer 150p may be reduced while the grain size thereof may be increased, thereby improving the electrical performance of the semiconductor memory device.

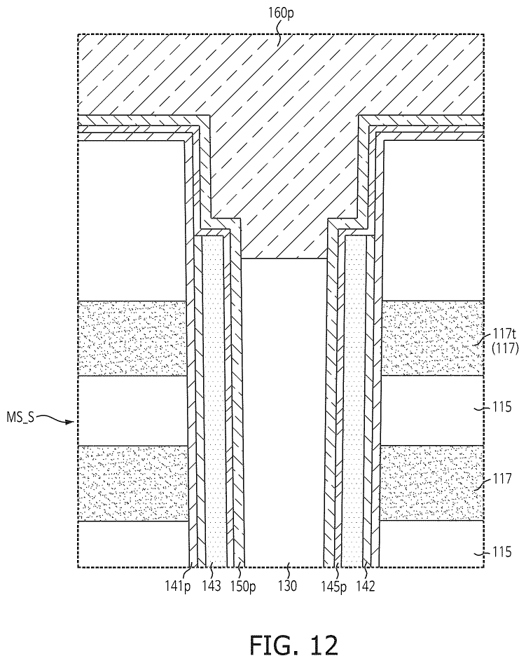

Referring to FIGS. 12 and 14, a filling insulating layer may be formed within the channel hole S170.

The channel hole CHH and an upper surface of the preliminary channel layer 150p may be filled with a preliminary filling insulating layer. The preliminary filling insulating layer may include an insulating material.

A portion of the preliminary filling insulating layer may be removed. For example, a portion of the preliminary filling insulating layer may be removed by a wet etching or a dry-cleaning process. The preliminary filling insulating layer may be removed to a predetermined depth by a recessing process. As such, a portion of the preliminary filling insulating layer may be removed to form the filling insulating layer 130.

Then, a preliminary channel pad 160p may be formed S180.

The preliminary channel pad 160p may be formed on the upper surface the filling insulating layer 130 and the preliminary channel layer 150p. The preliminary channel pad 160p may include a semiconductor material, such as polysilicon. In some implementations, the preliminary channel pad 160p and the preliminary channel layer 150p may be formed of the same material. In this case, the interface between the preliminary channel pad 160p and the preliminary channel layer 150p may not be identified.

Referring to FIGS. 13 and 14, a channel pad may be formed by performing a planarization process S190.

By the planarization process, the preliminary channel pad 160p, the preliminary channel layer 150p, the preliminary channel interface layer 145p, and the preliminary gate interface layer 141p may be removed. For example, the planarization process may be carried out by the chemical mechanical polishing (CMP).

Meanwhile, when the dielectric layer 142 is formed on the upper surface of the channel pad 160, residues may be generated during the planarization process. The dielectric layer 142 may be crystallized by the annealing process described with reference to FIG. 11 so that the hardness of the dielectric layer 142 may be increased, which may result in residues.

In the case of the method of manufacturing a semiconductor memory device according to the present disclosure, the dielectric layer 142 may not be placed at a level higher than the upper surface of the channel pad 160, so no residue may be generated during the planarization process.

Then, a mold sacrificial film, e.g., 117 in FIG. 12, may be removed through a block separation pattern, e.g., WC in FIG. 1, and the barrier layer 122 and the gate electrode 125 may be formed. For example, the mold sacrificial film 117 be removed by a wet etching.

The gate electrode 125 may be formed by filling a space formed by removing the mold sacrificial film 117 with a conductive material. The conductive material may include polycrystalline silicon or a metal silicide material.

Next, the contact plug 162 may be formed to penetrate the second interlayer insulating film 194. The contact plug 162 may be formed by filling a via hole penetrating the second interlayer insulating film 194 with a conductive material. The contact plug 162 may be in contact with the upper surface of each of the channel pad 160 and the channel layer 150. In the case of the semiconductor memory device according to the present disclosure, the area of the upper surfaces of the channel pad 160 and the channel layer 150 may be secured with a channel hole of a limited size, so that an area where the contact plug 162 can come into contact therewith may be secured. In addition, the diameter of the contact plug 162 may be secured, so the resistance may be reduced.

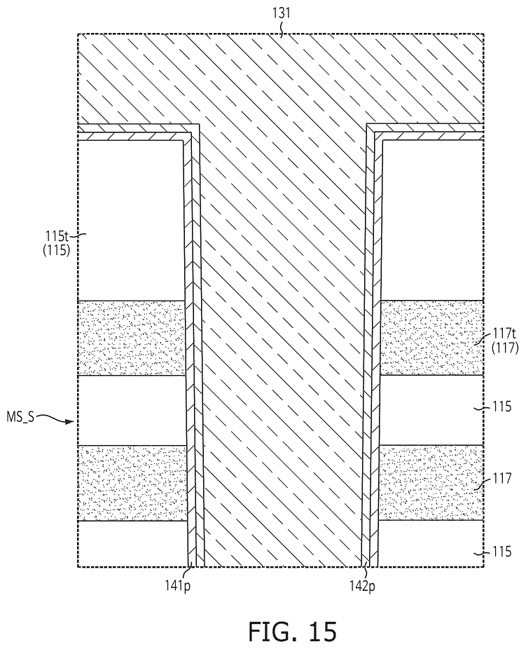

FIGS. 15, 16, 17, 18, and 19 are views for illustrating an example of a method of manufacturing a semiconductor memory device. For convenience of description, descriptions overlapping with those of FIGS. 7 to 14 will be skipped.

Referring to FIG. 15, after a channel hole is formed in the sacrificial mold structure MS_S, the preliminary gate interface layer 141p and the preliminary dielectric layer 142p may be conformally formed. The channel hole and the space on an upper surface of the preliminary dielectric layer 142p may be filled with the channel sacrificial film 131.

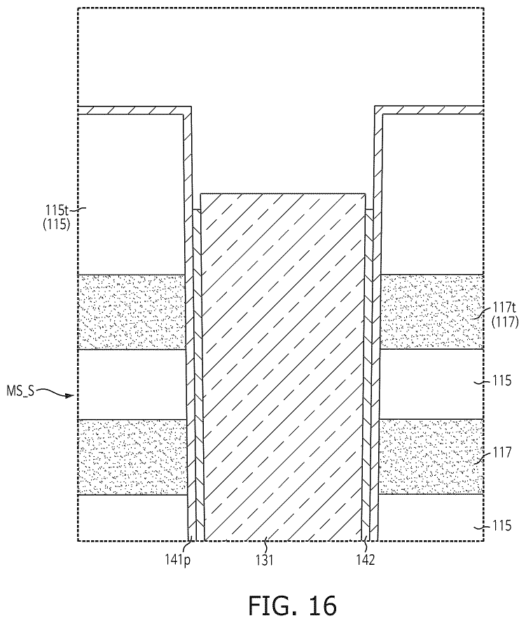

Referring to FIG. 16, after the channel sacrificial film 131 is recessed to a predetermined depth, a portion of the preliminary dielectric layer 142p may be removed. The preliminary dielectric layer 142p may include a material having a selectivity with respect to the channel sacrificial film 131 and the preliminary gate interface layer 141p. For example, a portion of the preliminary dielectric layer 142p may be removed by a wet etching.

A portion of the preliminary dielectric layer 142p may be removed to form the dielectric layer 142. The upper surface of the dielectric layer 142 may be located at a lower level than the upper surface of the channel sacrificial film 131.

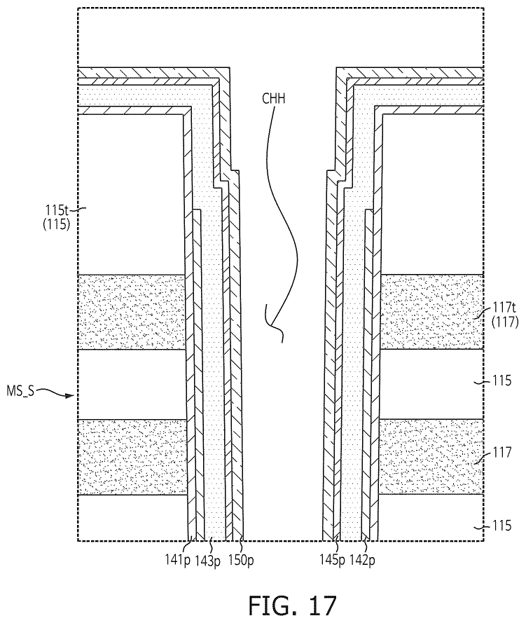

Referring to FIG. 17, after the channel sacrificial film 131 is removed the preliminary ferroelectric layer 143p, the preliminary channel interface layer 145p, and the preliminary channel layer 150p may be sequentially formed inside the channel hole. When the channel structure CH in FIG. 5 is manufactured, the step of forming the preliminary channel interface layer 145p may be skipped. The preliminary ferroelectric layer 143p, the preliminary channel interface layer 145p, and the preliminary channel layer 150p may be conformally formed. As described with reference to FIG. 11, the annealing and thinning processes may be performed on the preliminary channel layer 150p.

As the preliminary ferroelectric layer 143p, the preliminary channel interface layer 145p, and the preliminary channel layer 150p are formed after the dielectric layer 142 has been formed, a ferroelectric bend, e.g., 143b in FIG. 6, an interface bend, e.g., 145b in FIG. 6, and a channel bend, e.g., 150b in FIG. 6, may be formed.

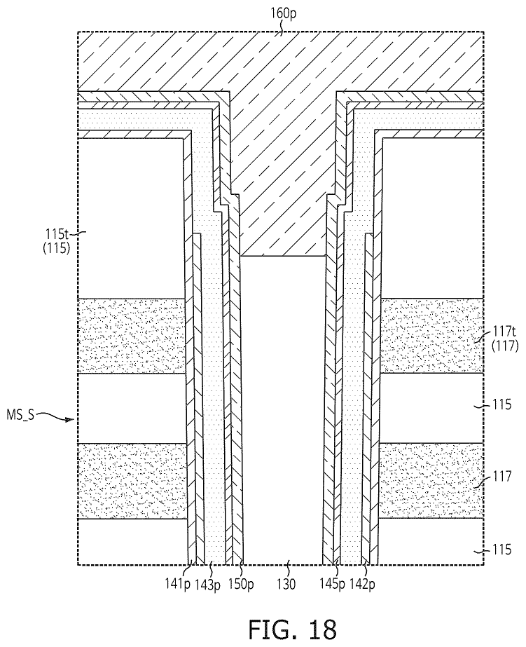

Referring to FIG. 18, the filling insulating layer 130 may be formed inside the channel hole CHH. For example, after the channel hole CHH and the space on the upper surface of the preliminary channel layer are filled with an insulating material to form a preliminary filling insulating layer, the recessing process may be performed, thereby forming the filling insulating layer 130.

The preliminary channel pad 160p may be formed on the upper surface of the filling insulating layer 130 and the upper surface of the preliminary channel layer 150p.

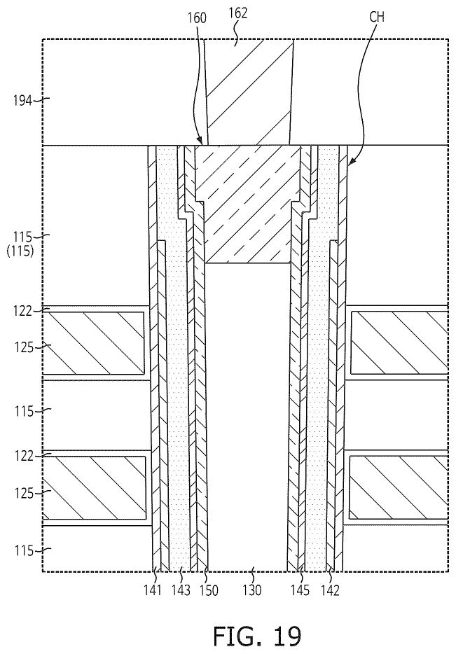

Referring to FIG. 19, by the planarization process, the preliminary channel pad 160p, the preliminary channel layer 150p, the preliminary channel interface layer 145p, and the preliminary gate interface layer 141p may be removed. For example, the planarization process may be performed by the chemical mechanical polishing (CMP).

Then, a mold sacrificial film, e.g., 117 in FIG. 18, may be removed, and the barrier layer 122 and the gate electrode 125 may be formed. For example, the mold sacrificial film 117 may be removed by a wet etching.

Next, the contact plug 162 may be formed to penetrate the second interlayer insulating film 194. The contact plug 162 may be formed by filling a via hole penetrating the second interlayer insulating film 194 with a conductive material. The contact plug 162 may be in contact with the upper surface of each of the channel pad 160 and the channel layer 150.

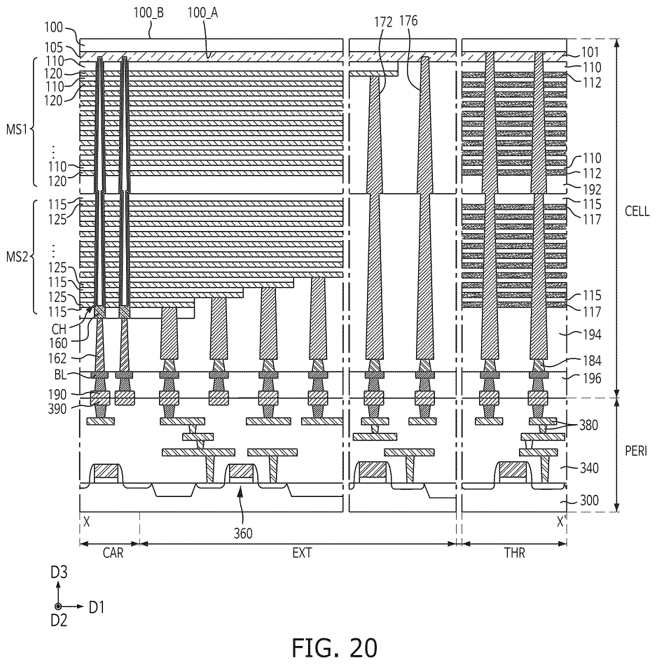

FIG. 20 illustrates an example of a semiconductor memory device.

Referring to FIG. 20, the semiconductor memory device may include a common source plate 105.

The common source plate 105 may be placed on the first side 100_A of the cell substrate 100. The common source plate 105 may be connected to the channel structure CH. For example, the common source plate 105 may be electrically connected to a semiconductor pattern of the channel structure CH. The common source plate 105 may be used as a common source line, e.g., CSL in FIG. 21, of the semiconductor memory device. The first mold structure MS1 and the second mold structure MS2 may be placed on the common source plate 105. The common source plate 105 may include, for example, polycrystalline silicon or a metal doped with impurities, but the present disclosure is not limited thereto.

The semiconductor memory device may have a chip to chip (C2C) structure. The C2C structure may be formed through the following process: An upper chip including a memory cell region CELL is formed on a first wafer, e.g., the cell substrate 100, and a lower chip including the peripheral circuit region PERI is formed on a second wafer, e.g., the peripheral circuit substrate 300, different from the first wafer. Then, the upper and lower chips are connected to each other by bonding.

For example, the bonding may mean electrically connecting a first bonding metal 190 formed on a top metal layer of the upper chip and a second bonding metal 390 formed on a top metal layer of the lower chip. For example, when the first bonding metal 190 and the second bonding metal 390 are formed of copper (Cu), the bonding may be a Cu-Cu bonding. However, this is only an example, and it is needless to say the first bonding metal 190 and the second bonding metal 390 may also be formed of various other metals, such as aluminum (Al) and tungsten (W).

As the first bonding metal 190 and the second bonding metal 390 are bonded, the first wiring structure 180 may be connected to a second wiring structure 280. As a result, the bit line BL and each of the gate electrodes 120 and 125 may be electrically connected to the peripheral circuit element 360.

FIG. 21 is a block diagram for illustrating an example of an electronic system.

Referring to FIG. 21, an electronic system 1000 may include a semiconductor memory device 1100 described above with reference to FIGS. 1 to 6 and 20 and a controller 1200 electrically connected to the semiconductor memory device 1100. The electronic system 1000 may be a storage device including one or more semiconductor memory devices 1100 or an electronic device including a storage device. For example, the electronic system 1000 may be a solid state drive (SSD) device, a universal serial bus (USB), a computing system, a medical device, or a communication device, including one or more semiconductor memory devices 1100.

The semiconductor memory device 1100 may be, for example, a NAND flash memory device described above with reference to FIGS. 1 to 6 and 20. The semiconductor memory device 1100 may include a first structure 1100F and a second structure 1100S on the first structure 1100F. The first structure 1100F may be a peripheral circuit structure including the decoder circuit 1110, the page buffer 1120, and the logic circuit 1130. The second structure 1100S may be a memory cell structure including the bit line BL, the common source line CSL, word lines WL, first and second gate upper lines UL1 and UL2, first and second gate lower lines LL1 and LL2, and memory cell strings CSTR between the bit line BL and the common source line CSL.

Each of the memory cell strings CSTR of the second structure 1100S may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of the lower transistors LT1 and LT2 and the number of the upper transistors UT1 and UT2 may vary depending on the implementations.

In some implementations, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connecting wires 1115 extending from the first structure 1100F to the second structure 1100S. The bit lines BL may be electrically connected to the page buffer 1120 through second connecting wires 1125 extending from the first structure 1100F to the second structure 1100S.

In the first structure 1100F, the decoder circuit 1110 and the page buffer 1120 may perform an operation of controlling at least one memory cell transistor selected from the plurality of memory cell transistors MCT. The decoder circuit 1110 and the page buffer 1120 may be controlled by the logic circuit 1130. The semiconductor memory device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends from the first structure 1100F to the second structure 1100S.

The controller 1200 may include a processor 1210, a NAND controller 1220, and a host interface 1230. In some implementations, the electronic system 1000 may include a plurality of semiconductor memory devices 1100, and the controller 1200 may control the plurality of semiconductor memory devices 1100.

The processor 1210 may control the overall operation of the electronic system 1000 including the controller 1200. The processor 1210 may operate according to a predetermined firmware and access the semiconductor memory device 1100 by controlling the NAND controller 1220. The NAND controller 1220 may include a NAND interface or controller interface 1221 that processes communication with the semiconductor memory device 1100. Through the NAND interface 1221, a control command for controlling the semiconductor memory device 1100, data to be written to the memory cell transistors MCT of the semiconductor memory device 1100, data to be read from the memory cell transistors MCT of the semiconductor memory device 1100, etc. may be transmitted. The host interface 1230 may function for communication between the electronic system 1000 and an external host. When receiving a control command from the external host through the host interface 1230, the processor 1210 may control the semiconductor memory device 1100 in response to the control command.

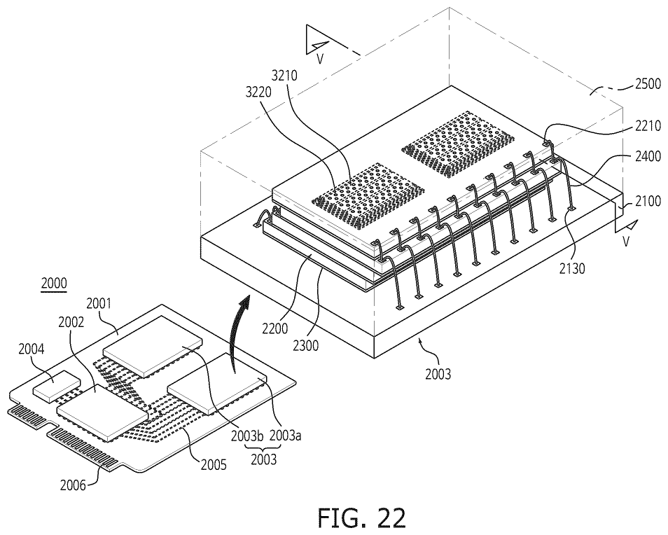

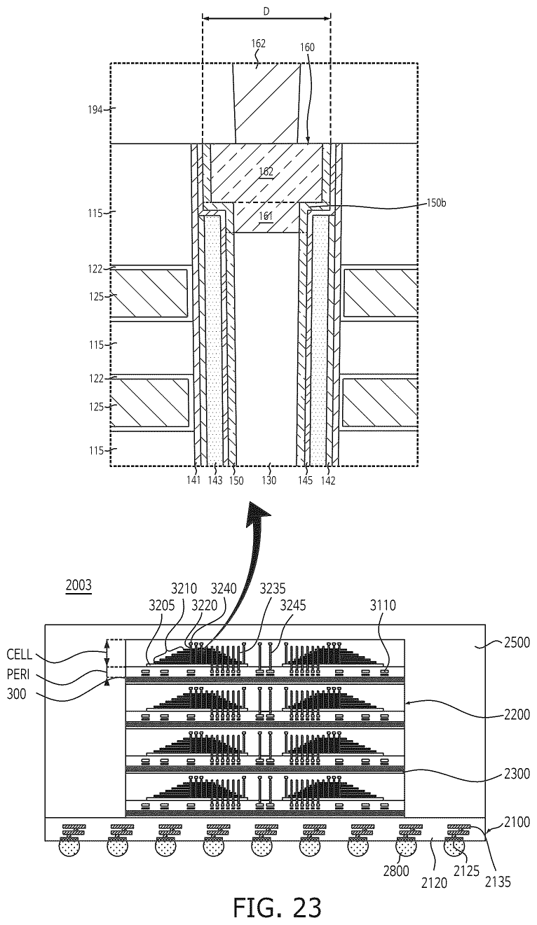

FIG. 22 is a perspective view for illustrating an example of an electronic system. FIG. 23 is an example schematic cross-sectional view taken along line V-V in FIG. 22.

Referring to FIG. 22, an electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins that are coupled with an external host. The number and arrangement of the plurality of pins of the connector 2006 may vary depending on a communication interface between the electronic system 2000 and the external host. In some implementations, the electronic system 2000 may communicate with an external host based on any one of the following interfaces: a universal serial bus (USB), a peripheral component interconnect express (PCI-Express), a serial advanced technology attachment (SATA), M-Phy for a universal flash storage (UFS), etc. In some implementations, the electronic system 2000 may be operated by power supplied from an external host through the connector 2006. The electronic system 2000 may further include a power management integrated circuit (PMIC) that distributes the power supplied from the external host to the controller 2002 and the semiconductor package 2003.

The main controller 2002 may write data to the semiconductor package 2003 or read data from the semiconductor package 2003, and may improve the speed at which the electronic system 2000 operates.

The DRAM 2004 may be a buffer memory to alleviate a difference in speed between the semiconductor package 2003, which is a data storage space, and an external host. The DRAM 2004 included in the electronic system 2000 may also function as a type of cache memory, and may provide a space for temporarily storing data during an operation of controlling the semiconductor package 2003. When the electronic system 2000 includes the DRAM 2004, the main controller 2002 may further include a DRAM controller for controlling the DRAM 2004 in addition to the NAND controller for controlling the semiconductor package 2003.

The semiconductor package 2003 may include a first semiconductor package 2003a and a second semiconductor package 2003b that are spaced apart from each other. The first semiconductor package 2003a and the second semiconductor package 2003b may each be a semiconductor package including a plurality of semiconductor chips 2200. The first semiconductor package 2003a and the second semiconductor package 2003b may each include a package substrate 2100, the semiconductor chips 2200 on the package substrate 2100, an adhesive layer 2300 arranged on a lower surface of each of the semiconductor chips 2200, a connecting structure 2400 electrically connecting the semiconductor chips 2200 and the package substrate 2100, and a molding layer 2500 covering the semiconductor chips 2200 and the connecting structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 in FIG. 21. Each of the semiconductor chips 2200 may include metal lines 3210 and channel structures 3220. Each of the semiconductor chips 2200 may include the semiconductor memory device as described above with reference to FIGS. 1 to 6 and 20.

In some implementations, the connecting structure 2400 may be a bonding wire that electrically connects the input/output pad 2210 and the package upper pads 2130. Accordingly, in each of the first semiconductor package 2003a and the second semiconductor package 2003b, the semiconductor chips 2200 may be electrically connected to each other by a bonding wire, and may be electrically connected to the package upper pads 2130 of the package substrate 2100. In some implementations, in each of the first semiconductor package 2003a and the second semiconductor package 2003b, the semiconductor chips 2200 may be electrically connected to each other by a connecting structure including a through silicon via (TSV), instead of the connecting structure 2400, which is a bonding wire.

In some implementations, the main controller 2002 and the semiconductor chips 2200 may be included in one single package. In some implementations, the main controller 2002 and the semiconductor chips 2200 may be mounted on an interposer substrate separate from the main substrate 2001, and the main controller 2002 and the semiconductor chips 2200 may be connected to each other by wiring formed on the interposer substrate.

In some implementations, the package substrate 2100 may be a printed circuit board. The package substrate 2100 may include a package substrate body 2120, the package upper pads 2130 disposed on an upper surface of the package substrate body 2120, lower pads 2125 placed on or exposed through a lower surface of the package substrate body 2120, and internal wirings 2135 electrically connecting the upper pads 2130 and the lower pads 2125 within the package substrate body 2120. The upper pads 2130 may be electrically connected to the connecting structures 2400. The lower pads 2125 may be connected to the wiring patterns 2005 of the main substrate 2001 of the electronic system 2000 as shown in FIG. 22 through conductive connectors 2800.

Each of the semiconductor chips 2200 of the electronic system may include the semiconductor memory device as described above using FIGS. 1 to 6 and 20. For example, each of the semiconductor chips 2200 may include the peripheral circuit structure PERI and the cell structure CELL stacked on the peripheral circuit structure PERI. For example, the peripheral circuit structure PERI may include the peripheral circuit substrate 300 and a peripheral wiring 3110 described above based on FIGS. 1 to 6 and 20. In addition, for example, the cell structure CELL may include a common source line 3205, a gate stacking structure 3210 on the common source line 3205, the channel structure 3220 and a separation structure 3230 penetrating the gate stacking structure 3210, a bit line 3240 electrically connected to the channel structure 3220, and a gate connecting wiring electrically connected to a word line of the gate stacking structure 3210.

Each of the semiconductor chips 2200 may include a through-wiring 3245 that is electrically connected to the peripheral wiring 3110 of the peripheral circuit structure PERI and extends into the cell structure CELL. The through-wiring 3245 may penetrate the gate stacking structure 3210 and may also be arranged outside the gate stacking structure 3210. Each of the semiconductor chips 2200 may further include an input/output connecting wiring 3265 electrically connected to the peripheral wiring 3110 of the peripheral circuit structure PERI and extending into a second structure 3200 and the input/output pad 2210 electrically connected to the input/output connecting wiring 3265.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the present disclosure has been described by means of the implementations and drawings, it is not limited thereto. It goes without saying that, by a person having ordinary skill in the technical field to which the present disclosure belongs, various modifications and variations can be made to the present disclosure within the scope of the technology of the present disclosure and the claims set forth below.

What is claimed is:

1. A semiconductor memory device comprising:
a mold structure comprising a plurality of mold insulating layers and a plurality of gate electrodes, wherein the plurality of mold insulating layers and the plurality of gate electrodes are alternately stacked in a first direction; and
a channel structure extending through the mold structure in the first direction,
wherein the channel structure comprises:
a filling insulating layer;
a channel layer on a side surface of the filling insulating layer;
a ferroelectric layer and a dielectric layer between the channel layer and the plurality of gate electrodes; and
a channel pad contacting the filling insulating layer and the channel layer,
wherein the channel pad comprises:
a first portion contacting an upper surface of the filling insulating layer; and
a second portion on the first portion and having a width larger than a width of the first portion in a second direction, the second direction being perpendicular to the first direction, and
wherein an upper surface of the dielectric layer is lower than the second portion.

2. The semiconductor memory device of claim 1, wherein the channel layer comprises a channel bend extending along a side surface of the first portion and a lower surface of the second portion.

3. The semiconductor memory device of claim 2, wherein an upper surface of the ferroelectric layer is lower than the second portion.

4. The semiconductor memory device of claim 3, wherein the upper surface of the ferroelectric layer is coplanar with the upper surface of the dielectric layer.

5. The semiconductor memory device of claim 3, wherein the upper surface of the ferroelectric layer contacts the channel bend.

6. The semiconductor memory device of claim 2, wherein the upper surface of the ferroelectric layer is coplanar with an upper surface of the channel pad.

7. The semiconductor memory device of claim 2, wherein the ferroelectric layer comprises a ferroelectric bend corresponding to the channel bend, and
wherein the ferroelectric bend contacts the channel bend.

8. The semiconductor memory device of claim 7, wherein the upper surface of the dielectric layer contacts the ferroelectric bend.

9. The semiconductor memory device of claim 2, wherein
the channel structure comprises a gate interface layer between the dielectric layer and the plurality of gate electrodes, and
an upper surface of the gate interface layer is coplanar with the upper surface of the channel pad.

10. The semiconductor memory device of claim 9, wherein
the channel structure comprises a channel interface layer between the channel layer and the gate interface layer, and
an upper surface of the channel interface layer is coplanar with the upper surface of the channel pad.

11. The semiconductor memory device of claim 10, wherein
the channel interface layer comprises an interface bend corresponding to the channel bend, and
the interface bend contacts the dielectric layer and the ferroelectric layer.

12. The semiconductor memory device of claim 1, wherein
the plurality of gate electrodes comprise a top gate electrode, the top gate electrode being closest to the channel pad in the first direction among the plurality of gate electrodes, and
the upper surface of the dielectric layer is higher than an upper surface of the top gate electrode.

13. The semiconductor memory device of claim 1, wherein a lower surface of the first portion is lower than the upper surface of the dielectric layer.

14. The semiconductor memory device of claim 1, wherein the dielectric layer comprises a high-k material.

15. A semiconductor memory device comprising:
a peripheral circuit structure; and
a cell structure on the peripheral circuit structure,
wherein the cell structure comprises:
a cell substrate;
a mold structure comprising a plurality of mold insulating layers and a plurality of gate electrodes, wherein the plurality of mold insulating layers and the plurality of gate electrodes are alternately stacked on the cell substrate in a first direction; and
a channel structure in a channel hole, wherein the channel hole extends through the mold structure in the first direction,
wherein the channel structure comprises:
a filling insulating layer;
a channel layer on a side surface of the filling insulating layer;
a ferroelectric layer comprising a ferroelectric material, wherein the ferroelectric layer is on a side surface of the channel layer;
a dielectric layer comprising a high-k material and the dielectric layer on a side surface of the ferroelectric layer; and
a channel pad contacting the filling insulating layer and the channel layer,
wherein the channel pad comprises:
a first portion contacting an upper surface of the filling insulating layer; and
a second portion on the first portion, wherein the second portion has a width larger than a width of the first portion in a second direction, the second direction being perpendicular to the first direction, and
an upper surface of the dielectric layer is lower than the second portion.

16. The semiconductor memory device of claim 15, wherein
the channel layer comprises a channel bend extending along a side surface of the first portion and a lower surface of the second portion, and
the channel bend overlaps the first portion in the second direction.

17. The semiconductor memory device of claim 16, wherein an upper surface of the ferroelectric layer and the upper surface of the dielectric layer contact the channel bend.

18. The semiconductor memory device of claim 16, wherein
the channel structure comprises a gate interface layer between the dielectric layer and the plurality of gate electrodes, and
an upper surface of the gate interface layer is coplanar with an upper surface of the channel pad.

19. The semiconductor memory device of claim 18, wherein
the channel structure comprises a channel interface layer between the channel layer and the gate interface layer, wherein an upper surface of the channel structure is coplanar with the upper surface of the channel pad, and
the channel interface layer comprises an interface bend corresponding to the channel bend and contacting the dielectric layer and the ferroelectric layer.

20. An electronic system comprising:
a main substrate;
a semiconductor memory device comprising a peripheral circuit structure and a cell structure, the cell structure being on the peripheral circuit structure, the peripheral circuit structure being on the main substrate; and
a controller electrically connected with the semiconductor memory device on the main substrate,
wherein the cell structure comprises:
a cell substrate;
a mold structure comprising a plurality of mold insulating layers and a plurality of gate electrodes, wherein the plurality of mold insulating layers and the plurality of gate electrodes are alternately stacked on the cell substrate in a first direction; and
a channel structure in a channel hole, wherein the channel hole extends through the mold structure in the first direction,
wherein the channel structure comprises:
a filling insulating layer;
a channel layer on a side surface of the filling insulating layer;
a ferroelectric layer and a dielectric layer between the channel layer and the plurality of gate electrodes; and
a channel pad contacting the filling insulating layer and the channel layer,
wherein the ferroelectric layer comprises a ferroelectric material, and the dielectric layer comprises a high-k material,
wherein the channel pad comprises:
a first portion contacting an upper surface of the filling insulating layer; and
a second portion on the first portion, the second portion having a width larger than a width of the first portion in a second direction, the second direction being perpendicular to the first direction, and
wherein an upper surface of the dielectric layer is lower than the second portion.
